(19) United States
(12) Patent Application Publication
(10) Pub. No.: US 2015/0142345 A1
(43) Pub. Date: May 21, 2015

(54) Status Monitoring Systems and Methods for Uninterruptible Power Supplies

(71) Applicant: Alpha Technologies Inc., Bellingham, WA (US)

(72) Inventors: Robert P. Anderson, Lynden, WA (US); Pankaj H. Bhatt, Bellingham, WA (US); John R. Hewitt, Bellingham, WA (US); Ronald J. Roybal, Bellingham, WA (US)

(21) Appl. No.: 14/516,522

(22) Filed: Oct. 16, 2014

Related U.S. Application Data
(60) Provisional application No. 62/053,763, filed on Sep. 22, 2014.
(60) Provisional application No. 62/037,461, filed on Aug. 14, 2014.
(60) Provisional application No. 61/892,648, filed on Oct. 18, 2013.

(51) Int. Cl. G01R 31/08; G01R 31/02

(52) U.S. Cl. CPC G01R 31/088; G01R 31/021
USPC 702/59

(57) ABSTRACT

A power supply system for use in a communications system comprises a power supply, a cable interface module, and a processor. The power supply is connected to a local supply, a utility supply, and the communications system. The cable interface module detects an FBC signal associated with the communications system. The processor executes a monitoring process in which the processor monitors the FBC signal for characteristics associated with at least one anomaly and generates a trap signal when an anomaly is detected.

### RELATED APPLICATIONS

This application (Attorney's Ref. No. P218168) claims benefit of U.S. Provisional Applications Ser. Nos. 62/053,763 filed Sep. 22, 2014, 62/037,461 filed Aug. 14, 2014, and 61/892,648 filed Oct. 18, 2013, the contents of which are incorporated herein by reference.

### TECHNICAL FIELD

The present invention relates to power supplies for use in distribute communications networks and, more particularly, to power supplies capable of detecting and identifying network impediments.

### BACKGROUND

Communications networks such as cable TV (CATV) networks include numerous components distributed throughout a dispersed geographic area. Impediments to proper or optimal operation of the CATV network (anomalies) include:
Frequency specific lack of power or a “notch” of low or missing signal;
Signal tilt, in which the RF energy is higher at one end of the measured range than the other;
Repeating ripples in power amplitude, which is characteristic of an impedance mismatch on the coax plant;
Ingress from on-air transmissions such as interference from cell towers, radio stations or other sources of RF energy; and
Frequency roll-off at or near the top of the spectrum.

Cable Operators today use expensive, dedicated network analysis equipment to identify and troubleshoot these and other signal impediments. The root cause for these impediments or anomalies can be identified by the cable operator through experience and analysis of the measured signals.

In addition, chip sets from companies such as Broadcom (e.g., Broadcom DOCSIS 3.0 system-on-a-chip family) and Intel (e.g., Puma family) allow communications systems to be monitored in real time to for signal transmission characteristics. These chip sets do not detect and locate network impediments or anomalies associated with or unique to a particular communications system or that occur over time.

The need exists for improved systems and methods of detecting and identifying impediments in distributed communications networks that does not require expensive, dedicated network analysis equipment or the expertise of experienced cable operators.

### SUMMARY

A power supply system for use in a communications system comprises a power supply, a cable interface module, and a processor. The power supply is connected to a local supply, a utility supply, and the communications system. The cable interface module detects an FBC signal associated with the communications system. The processor executes a monitoring process in which the processor monitors the FBC signal for characteristics associated with at least one anomaly and generates a trap signal when an anomaly is detected.

The present invention may also be embodied as a method of providing power to a communications system comprising the following steps. A power supply is connected to a local supply, a utility supply, and the communications system. A cable interface module is arranged to detect an FBC signal associated with the communications system. The FBC signal is monitored for characteristics associated with at least one anomaly. A trap signal is generated when an anomaly is detected.

### BRIEF DESCRIPTION OF THE DRAWINGS

FIG. 1 is a block diagram depicting a simplified representative Cable Television Hybrid-Fiber Coax (HFC) network architecture in which a status monitoring system of the present invention may be used;

FIG. 2 is a block diagram depicting an example transponder system of the present invention;

FIG. 3 is a block diagram illustrating an example cable modem RF system of the transponder system of the present invention;

FIG. 4 is a block diagram illustrating a transponder monitoring system of the transponder system of the present invention;

FIG. 5 is a block diagram illustrating cable modem digital system of the transponder system of the present invention;

FIG. 6 depicts an example web page generated by the example transponder system to display a constellation graph;

FIGS. 7-10 depict several example visual representations of Graphic Equalization Displays;

FIG. 11 is a block diagram depicting a calibration test set up used to implement a temperature compensated equalizer normalization process;

FIG. 12 depicts an example user interface (e.g., Web page) displaying a constellation diagram;

FIG. 13 depicts a user interface of the present invention configured to display downstream bonded channels in a vertical bar;

FIG. 14 depicts an example micro reflections/group delay diagram that may be displayed by the user interface of the present invention;

FIG. 15 illustrates a user interface programmed to display timing and distance to impediment calculations;

FIG. 16 illustrates a user interface displaying an ICFR generated using a FFT (Fast Fourier Transform) of the 24-tap pre-equalizer data in the graph in FIG. 15;

FIG. 17 is a display illustrating a method of detecting changes in RF signal levels resulting from: spurs, noise, tilt, drop-outs, and other undesirable spectral activity;

FIG. 18A is a logic flow diagram illustrating an example of logic that may be used to implement a baseline setting portion of the method associated with FIG. 17;

FIG. 18B is a logic flow diagram illustrating an example of logic that may be used to implement a real time monitoring portion of the method associated with FIG. 17;

FIG. 19 illustrates a data pattern that may be analyzed when performing Frequency Response Ripple Analysis;

FIG. 20 illustrates the use of spectral tilt analysis to identify linear variation in spectral energy across the measured spectrum;

FIG. 21 illustrates a data pattern representative of frequency suck-out that may be determined by notch analysis;

FIG. 22 illustrates the use of frequency spike analysis to identify frequency spectral amplification caused by faulty amplifiers;

FIG. 23 illustrates the use of ingress carrier analysis to determine the “ingress” of LTE, FM, UHF, and other frequency specific signals onto the coaxial cable system;

FIG. 24 illustrates the use of relative channel level analysis to determine whether a channel is either too high or too low relative to adjacent channels;

FIG. 25 illustrates the use of dropped channel(s) analysis to determine whether a channel level has dropped to ˜0 level;

FIG. 26 illustrates the use of frequency roll-off analysis to analyze the signal for the existence of non-linear amplitude drop at the edge of measured spectrum by detecting frequency specific power loss; and

FIG. 27 illustrates the use of individual channel analysis to review each QAM channel for any anomalous measurements.

### DETAILED DESCRIPTION

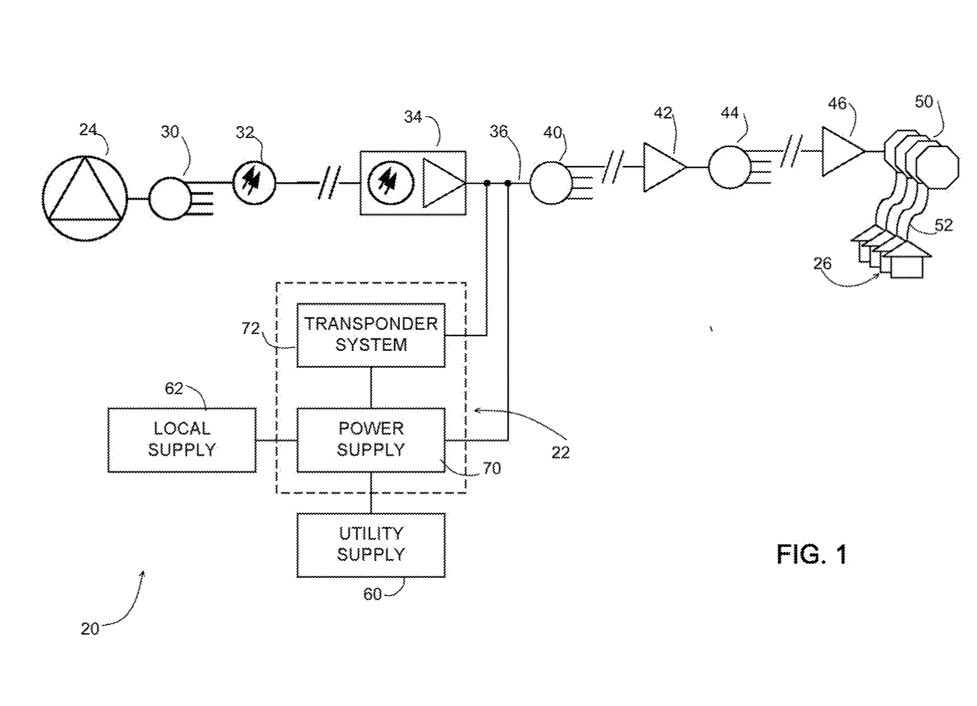

Referring now to FIG. 1 of the drawing, depicted therein is an example communications network 20 incorporating a power supply system 22 of the present invention. The example communications network comprises a headend 24 that transmits signals to and receives signals from one or more premises 26. FIG. 1 further shows that the example headend 24 comprises a fiber optical splitter 30. As is conventional, the fiber optical splitter 30 defines at least one fiber optic input and at least one fiber optic output associated with the headend 24.

In the example network 20, a fiber optic cable system 32 carries fiber optical signals from the fiber optical splitter 30 to an optical node 34. The optical node 34 converts the fiber optical signals transmitted from the headend 24 to the premises 26 to electrical signals (downstream) and electrical signals transmitted from the premises to the headend 24 to fiber optical signals (upstream). The electrical signals are transmitted through a coaxial cable system 36.

The electrical signal output from the optical node 34 is transmitted using coaxial cable to a first coaxial splitter 40. The first coaxial splitter 40 splits the electrical signal into one or more electrical output signals. One representative electrical output from the first coaxial splitter 40 is connected to a first amplifier 42 which amplifies the electrical signal, allowing the electrical signal to be transmitted over greater distances. In the example communications network 20, the output from the first amplifier 42 is sent to a second coaxial splitter 44 and then to a second amplifier 46.

The output of the second amplifier 46 is sent to one or more taps 50, where the electrical signal is tapped and sent through drop cables 52 directly to individual homes or businesses forming the one or more premises 26. Each of the premises 26 contains Customer Premise Equipment (CPE) (not shown), which converts the electrical signal into a form usable by appliances, such as computers and televisions, within the premises 26.

The example power supply system 22 supplies power from a utility power source 60 to the optical node 34 and to the first and second amplifiers 42 and 46 through the same coaxial cable system 36 used to transmit electrical signals between the optical node 34 and the premises 26. The example power supply system 22 may further be capable of providing power from a local source 62 comprising batteries, an engine generator, solar power system, and/or other electrical generation means. The example power supply system 22 may further be embodied as an uninterruptible power supply (UPS). When embodied as a UPS, the example power supply system 22 is capable of supplying standby electrical power to the components (e.g., optical node 34, first amplifier 42, second amplifier 46) of the communications network 20 from the local source 62 when the primary power signal generated by the utility 60 falls outside of predetermined parameters.

The example power supply system 22 is further capable of performing qualitative evaluation of a network RF signature associated with the communications network 20. By using the example power supply system 22, and other such uninterruptible power supplies 22 distributed throughout the communications network 20, the operators of the communications network 20 can evaluate the network RF capabilities of the example communications network 20.

In particular, the example power supply system 22 includes a power supply 70 and a transponder system 72 for reporting power supply status, alarms, and other information to a monitoring system 72 associated with or located in the headend 24.

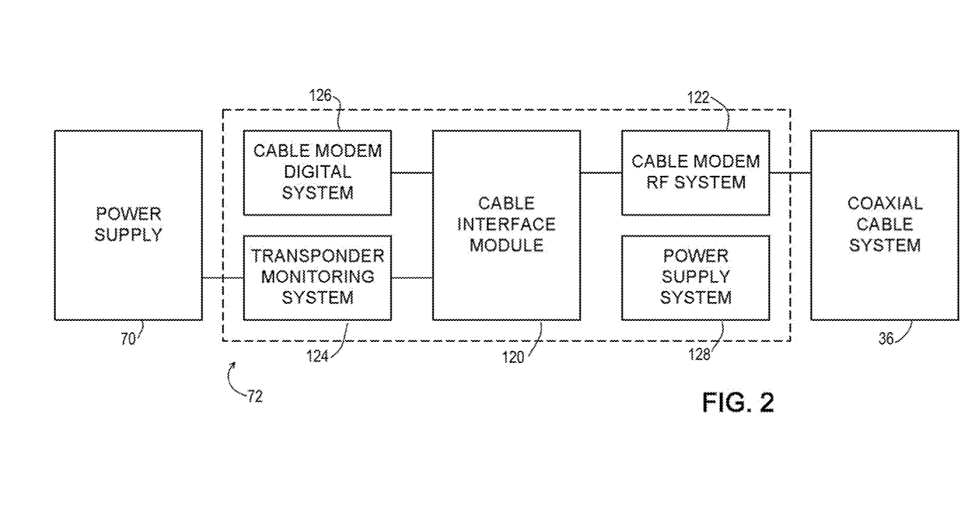

Referring now to FIG. 2 of the drawing, depicted therein is a block diagram of the example transponder system 72 of the present invention. The example transponder system 72 comprises a cable interface component 120, a cable modem RF system 122, a transponder monitoring system 124, and a cable modem digital system 126, and power supply components 128. The example transponder system 72 adheres to industry standard communication protocols, including DOCSIS 3.0. The power supply components 128 are or may be conventional and will and will not be described herein in further detail.

The example cable interface component 120 is, in the example transponder system 72, the Broadcom 3383D cable gateway chip (the Broadcom 3383 component).

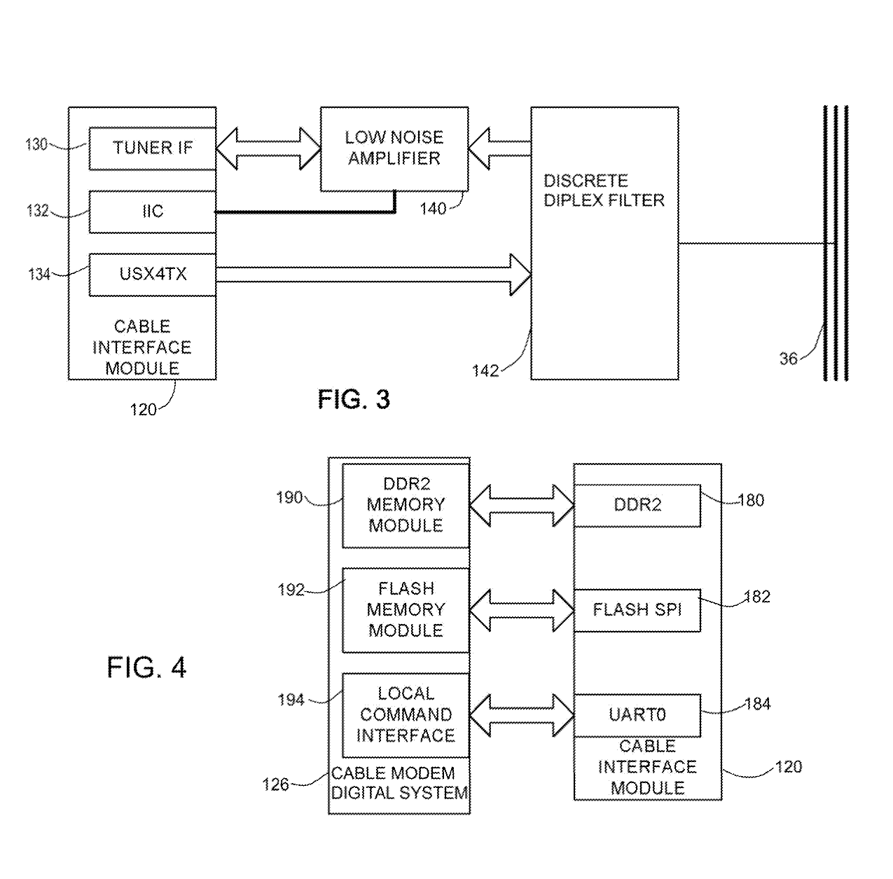

As shown in more detail in FIG. 3, the example cable interface component 120 defines a DS TUNER IF port 130, an IIC port 132, and a USX4TX port 134. The example cable modem RF system 122 comprises a low noise amplifier 140 and a discrete diplex filter 142. The low noise amplifier 140 is connected to the DS TUNER IF port 130 and to the IIC port 1232. The discrete diplex filter 142 is connected to the low noise amplifier 140, the USX4TX port 134, and the coaxial cable system 36.

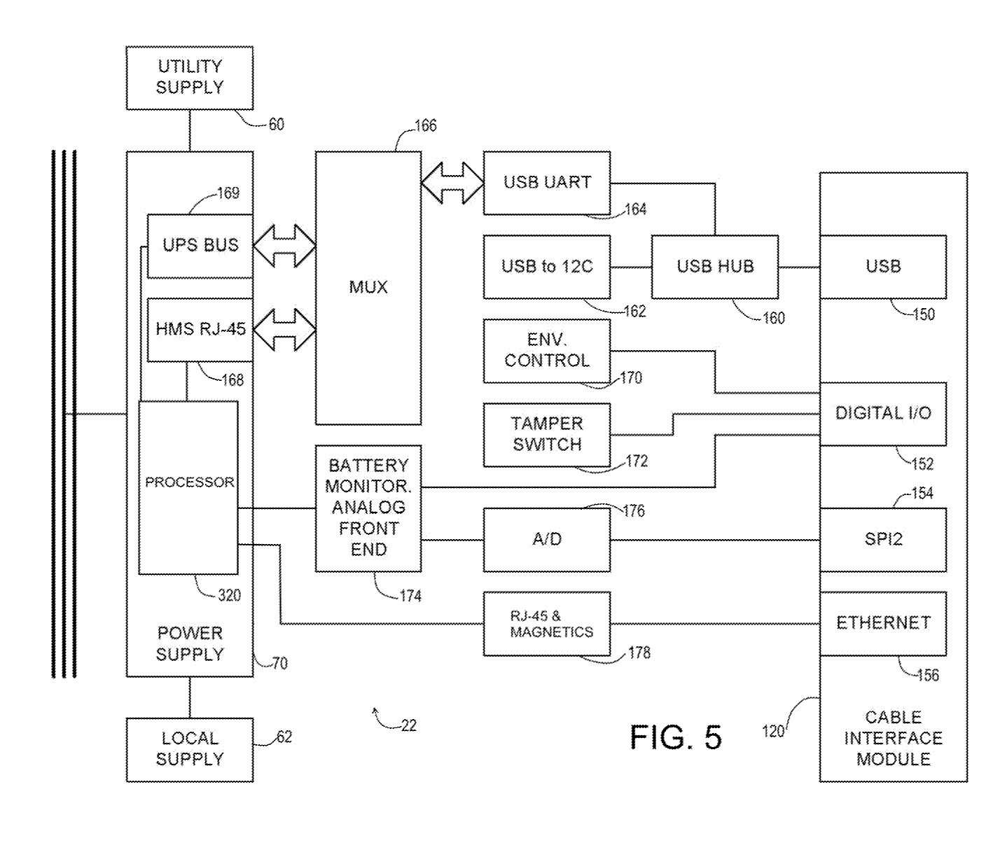

FIG. 5 illustrates that the example cable interface component 120 also defines a USB port 150, a digital I/O port 152, an SPI port 154, and an Ethernet port 156. The example transponder monitoring system 124 comprises a USB hub 160, a USB to 12C interface 162, a USB UART 164, a communications multiplexer 166, and a RJ-45 port 168. The USB hub 160 is connected to the USB port 150 and to the USB to 12C interface 162 and the USB UART 164. The USB UART 164 is in turn connected to the communications multiplexer 166. The communications multiplexer 166 is connected to an internal bus 169 of the power supply system 22 and to the digital I/O port 152. The example transponder monitoring system 124 also comprises an environmental control component 170 and a tamper switch 172 connected to the digital I/O port 152. The example transponder monitoring system 124 further comprises a battery monitoring and analog frontend 174 and an ND converter 176. The frontend 174 is connected to the digital I/O port 152 and, through the ND converter 176, to the SPI port 154. The example transponder monitoring system 124 also comprises an RJ-45 and magnetics component 178 connected to the Ethernet port 156.

As shown in FIG. 4, the example cable interface component 120 further defines a DDR2 port 180, a Flash SPI port 182, and a UART port 184. The example cable modem digital system 126 comprises a DDR2 memory module 190, a Flash memory module 192, and a local command line interface module 194. The DDR2 memory module 190 is connected to the DDR2 port 180, the Flash memory module 192 is connected to the Flash SPI port 182, and the local command line interface module 194 is connected to the UART port 184.

The example cable interface component 120 of the example transponder system 72 is a DOCSIS 3.0 compliant component from Broadcom known as the 3383. The Broadcom 3383 component includes network analysis capabilities for diagnosing network problems or impediments commonly referred to as Full Band Capture (FBC). FBC can view the signal level on the entire downstream RF spectrum from 80 MHz to 1,000 MHz and provide a signal amplitude for individual frequencies within this spectrum. By analyzing these signal amplitudes through software, network impediments can be identified and categorized and, in many cases, the root cause of the impediment can be discerned.

Examples of impediments that can be identified through software analysis using the example transponder system 72 include:
Frequency specific lack of power or a “notch” of low or missing signal;
Signal tilt, in which the RF energy is higher at one end of the measured range than the other;
Repeating ripples in power amplitude, which is characteristic of an impedance mismatch on the coax plant;
Ingress from on-air transmissions such as interference from cell towers, radio stations or other sources of RF energy; and
Frequency roll-off at or near the top of the spectrum.

For example, a ripple on the RF signal usually means an impedance mismatch in the coax. Impedance mismatches are often caused by corrosion in connectors. A micro reflections diagram tool of the example transponder system 72 can use the signal strength and frequency of the ripple to identify reflected power (i.e., some portion of the RF energy is reflected back towards the signal source when the primary signal encounters an impedance mismatch point in the network). Knowing the reflected power delay loop time and the propagation speed of the signal through the coax, the micro reflection tool can provide a close estimate of the distance from the power supply transponder to the offending location in the network. As generally discussed above, this location will often be a tap or splitter with a corroded connection.

The example transponder system 72 of the example power supply 22 implements Quality of Service (QoS) features network PHY layer quality at the power supply physical location in the network to be monitored. These features are implemented in the example transponder system 72 using the example cable interface component 120 with no additional hardware or firmware required. This text refers to the QoS features in the DSM33 as a QoS Network Probe or “probe”.

In addition to providing FBC (e.g., Broadcom FBC) capabilities, the firmware of the example transponder system 72 implements (1) Transport Stream Recording, (2) RF Constellation, and (3) Micro Reflections network analysis tools.

To support the Transport Stream Recording network analysis tool, the example transponder system 72 supports recording of the FCB data at user programmable recording periods. The recorded information will be stored in RAM for later download and analysis. The recorded stream can be triggered to capture an event occurring at any recorded frequency. This feature enables the logging and analysis of fast or impulse events that will not normally be captured during periodic FBC polls from the remote monitoring system.

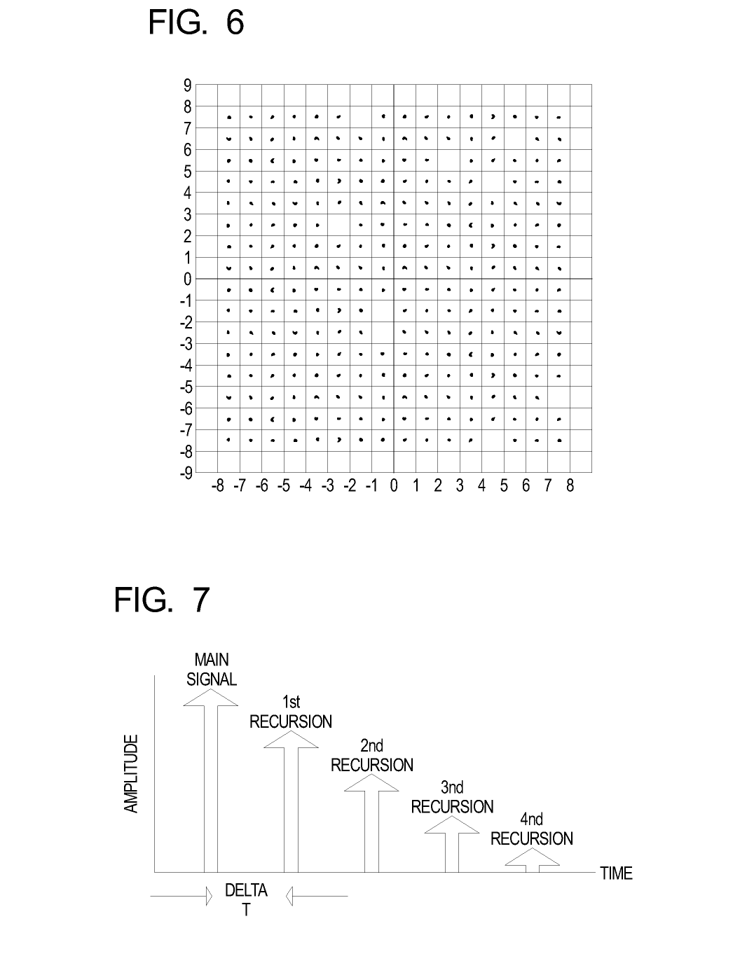

As depicted in FIG. 6, the example transponder system 72 maintains a web page displaying a constellation display, thereby providing a graphical view of the demodulated quadrature amplitude modulated (QAM) signal. The graphical display of the QAM signal allows quick identification of impairments such as gain compression or I-Q imbalance. The information from the visual appearance of the constellation display can be used to isolate and troubleshoot problems.

Turning now to the Micro Reflections network analysis tool, the example transponder system 72 maintains a Microreflections web page that displays the impairments and provides the approximate distance(s) of those impairment(s). The upstream pre-equalization mechanism relies on the interactions of the (DOCSIS) ranging process implemented by the example in order to determine and adjust the cable modem (CM) pre-equalization coefficients. The intent is for the CM to use its coefficients to pre-distort the upstream signal such that the pre-distortion equals the approximate inverse of the upstream path distortion, so that as the pre-distorted upstream signal travels through the network it is corrected and arrives free of distortion at the upstream receiver at the cable modem termination system (CMTS).

In the example transponder system 72, impairment distance may be calculated as follows. Initially, the delay or spacing between each adaptive equalizer tap location may be equal to the symbol period, because it always has a parameter of adaptive equalizer taps/symbol equal to 1.

In this case, the ‘Impairment Distance’ is calculated as follows (assuming ‘Symbol Period’ is 0.195 μs):

TAP1=(195/1.17)/2=83 feet

(1.17 ns per foot for 87% velocity of propagation coax, divide by two to account for the reflection's round trip).

TAP2=(195*2/1.17)/2=166 feet

Alternatively, the delay between different adaptive equalizer tap locations can be a fraction of a symbol period. That is, the number of equalizer taps/symbol parameter is allowed to be 1, 2 or 4, resulting respectively in delay differences between adaptive equalizer tap locations of T, T/2 and T/4. In this case, the exact impairment distance calculations may differ from the example set forth above.

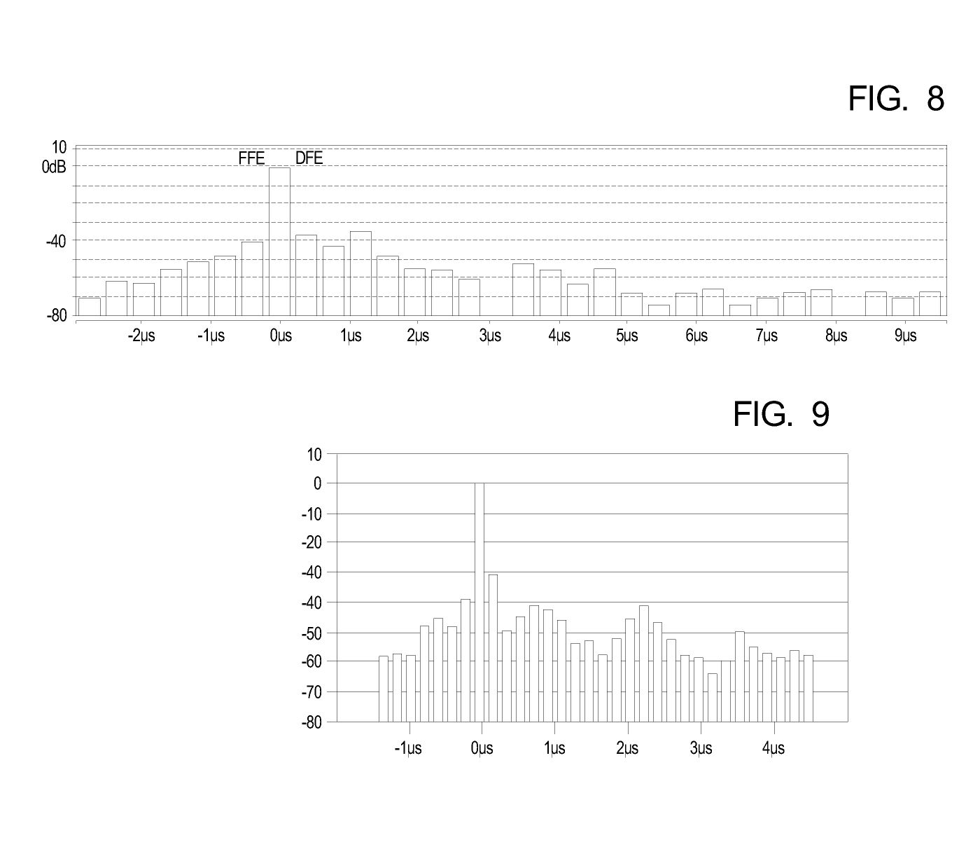

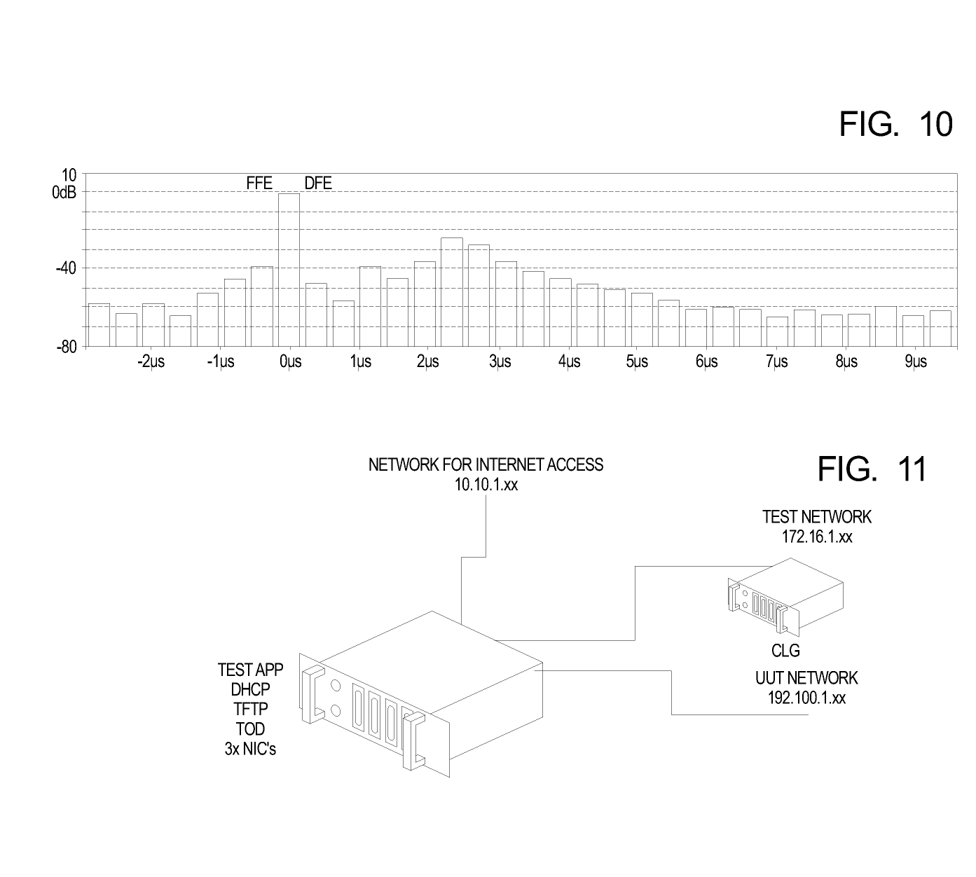

Referring now to FIGS. 7-10, depicted therein are several examples of visual representations of Graphic Equalization Displays. In any of these examples, a reference line may be displayed on the graph based on the following associations:

−10 dBc @<=0.5 μsec;

−20 dBc @<=1.0 μsec; and

−30 dBc @>1.0 μsec.

Referring now to FIG. 11 of the drawings, a temperature compensated equalizer normalization process implemented by the example transponder system 72 will now be described. The example transponder system 72 is specified to operate in a temperature range of −40 C. to +65 C. To assure accurate RF measurements over the entire downstream spectrum serviced with the FBC feature, certain coefficients in the example transponder system 72 should be factory calibrated using the calibration set up depicted in FIG. 11. These coefficients are derived from an algorithm which both compensates for circuit tolerance differences across batches of manufactured units and factors in the effect of actual operating temperature on RF measurements. This specific calibration will be generally described below with reference to FIG. 11.

The factory calibration method includes the use of a cable loading generator (CLG) 220 operatively connected to the example power supply 22 containing the example transponder system 72. The CLG 220 comprises a single output port that supports 158 digitally modulated channels. The cable interface between the CLG and UUT must be kept as short possible and routinely inspected and swept on a Network Analyzer for peak linear performance. The factory calibration process effectively eliminates or offsets the effects of the non-linearity of the RF path on the transponder from the equalizer coefficients for each cable modem channel. Based on the internal structure of the IF filtering of the example transponder system 72, it may also be necessary to calibrate the coefficients based on the channel's position in the IF filter to compensate for any roll off seen at the filter edges. The fully loaded downstream is fed directly into the transponder at 0 dB per channel. The transponder locks onto each channel and retrieves the downstream equalizer coefficients. The negative of these coefficients are the calibration data. When performing any spectral measurement based on the equalizer coefficients, in-channel frequency response (ICFR), Channel Group Delay, or Phase, the factory coefficients that represent the PCB and component non-linearity are subtracted out prior to any calculations. An example would be performing a Fast Fourier Transform (FFT) on the coefficients to obtain the frequency response or group delay characteristics of a specific channel.

As described above, the example transponder system 72 is implemented using a cable interface chip 120 sold as the Broadcom 3383 series of DOCSIS components. In this case, the cable interface chip 120 supports spectral Full Band Capture (FBC) and is capable of being used for a broad range of network diagnostic tools. The following discussion thus assumes that the cable interface chip 120 as implemented provides the full range of network diagnostic tools of the Broadcom 3383 component or the equivalent.

Accordingly, the example transponder system 72 is capable of providing Full Band Diagnostics using SNMP Management Information Base (MIB) files, a Web graphical display, and a constellation display.

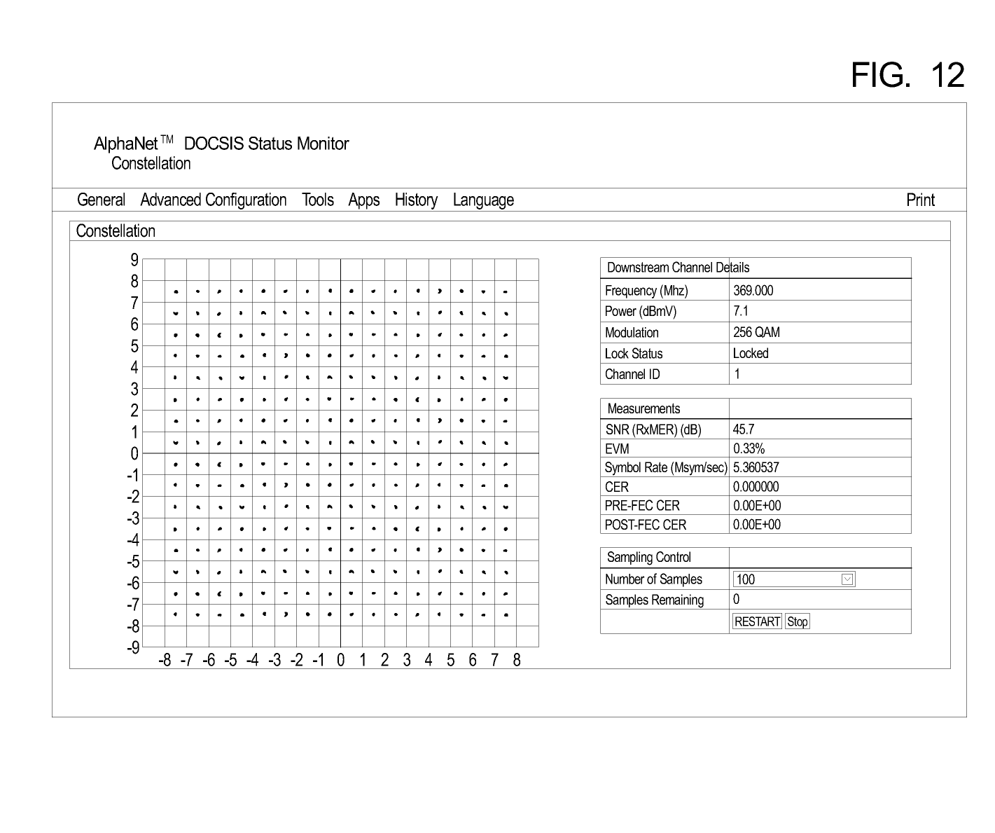

Referring initially to FIG. 12 of the drawing, depicted therein is a user interface (e.g., Web page) displaying a constellation diagram implemented by the example transponder system 72. In addition, the example transponder system may display from 2-8 bonded channels associated with any constellation display. The user interface depicting the example constellation display of FIG. 12 further includes various data and metrics (e.g., frequency, channel power, etc.) associated with the constellation display.

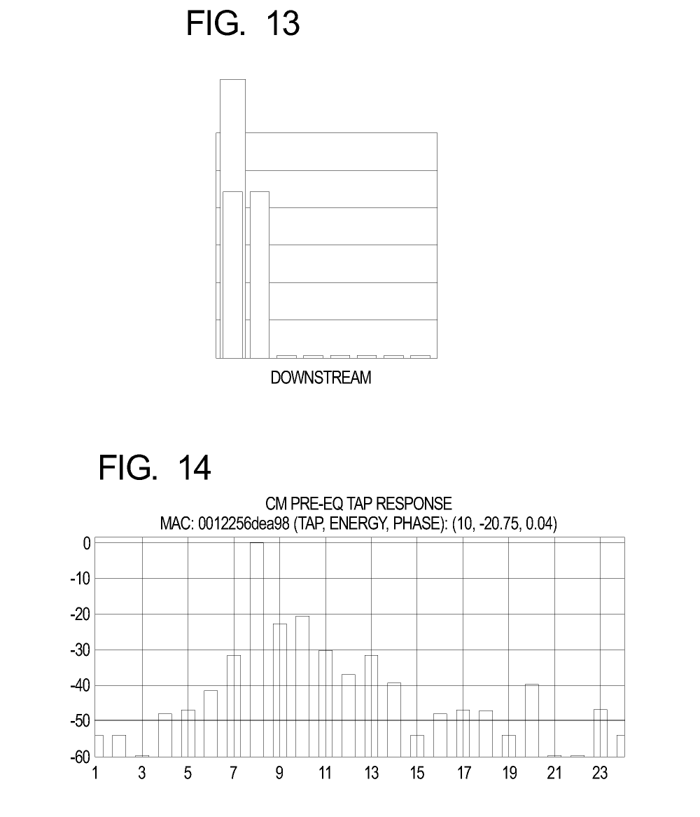

In addition, FIG. 13 illustrates that the user interface may display downstream bonded channels in a vertical bar for quick access. In this example, the display will vary from one vertical bar (representing no bonded channels in this group) to eight vertical bars (representing the maximum number (8) of DS bonded channel configuration channels). In this case, bar height indicates relative power levels for each channel. In particular, the vertical bar may show the relative amplitude of each channel. FIG. 13 depicts two downstream bonded channels. The user could select either bonded channel, in which case the respective constellation and metrics for that bonded channel would be displayed. When the user hovers on the bar, the frequency and channel number are shown as a tool tip. Additionally, an active pointer display and/or graph X-axis may be used to show channel and/or frequency. The selected channel to be displayed in the constellation diagram may be highlighted. The bar position may be static relative to the constellation diagram.

Turning now to FIG. 14 of the drawing, depicted therein is an example micro reflections/group delay diagram that may be displayed by the web page of the example transponder system 72. In the example depicted in FIG. 14, the Y-axis represents signal amplitude and the X-axis shows bars representing a 24-tap upstream equalizer. In the depicted example, the main tap is tap 8. Micro reflections are represented on each bar after the main tap 8. Group delays are represented on each bar before the main tap 8.

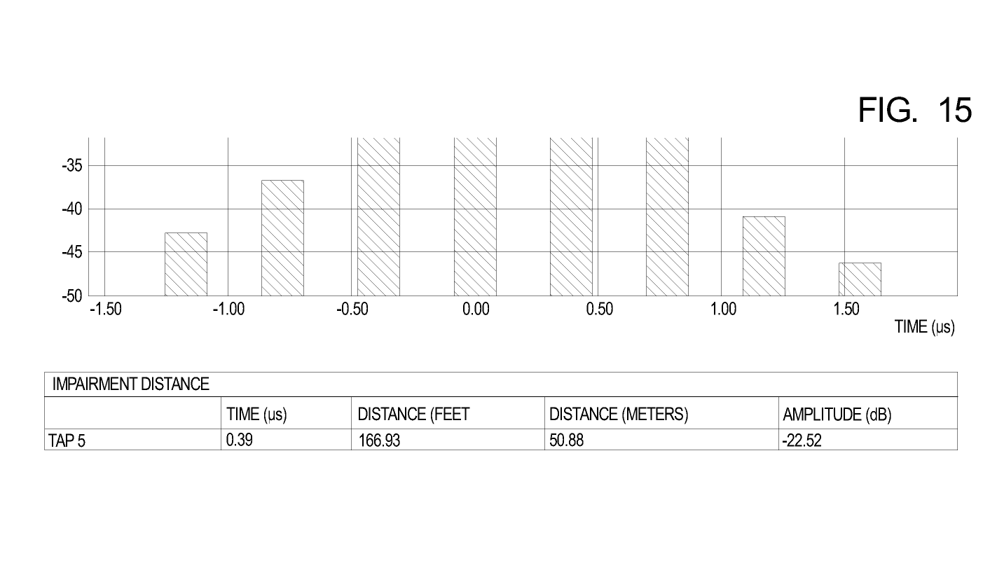

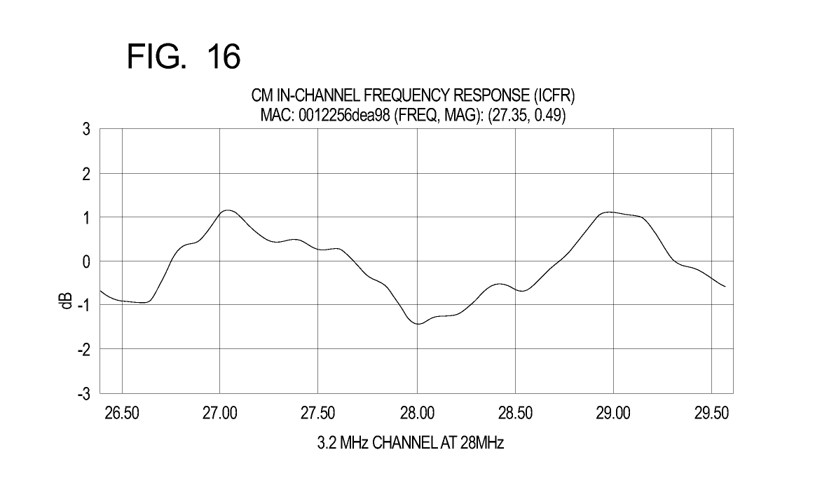

Referring now to FIG. 15 of the drawing, it can be seen that the user interface may also be programmed to display timing and distance to impediment calculations. Additional information may be added to the micro-reflection display (i.e., similar to the information display for the downstream constellation). Such additional display information may include upstream transmit power, correctable/uncorrectable CW errors, center frequency, bandwidth, modulation, CM IP address, and log history (log file in modem). The four additional ingress cancellation taps (around the main tap) would typically not be displayed graphically. In this case, an additional status indicator (e.g., Ingress Under Carrier) may be displayed as a warning with the other channel status information.

If upstream bonding is active, a vertical bar may be shown for each of the four possible bonded channels to allow the user to select a channel in the bonded group for pre-equalizer display and statistics display on that channel. In this case, a format similar to the bonded channel vertical bar display in the downstream constellation feature may be used.

A selection button on the micro-reflection display labeled “ICFR” may be used to display the In Channel Frequency Response (ICFR) for the upstream channel under observation. The FFT (Fast Fourier Transform) of the 24-tap pre-equalizer data in the graph in FIG. 15 yields an ICFR as shown in FIG. 16 of the drawing. The example ICFR depicted in FIG. 16 corresponds to a “Red” (nearly defective) modem because its micro reflection level is calculated based on the tap values to be −16.6 dB. In this example, a micro reflection value of less than −18 dB would be considered defective.

In some situations, a predetermined number (e.g., 4) of additional taps (e.g., ingress cancellation taps) are arranged around the main tap. Such additional taps may be hidden or displayed. Ingress cancellation taps are quite powerful and can help identify the presence of aggressors under QAM channels. The example transponder system 72 does not display such ingress cancellation taps but shows warnings when ingress under the carrier is detected. Based on field experience, these taps may be graphically displayed.

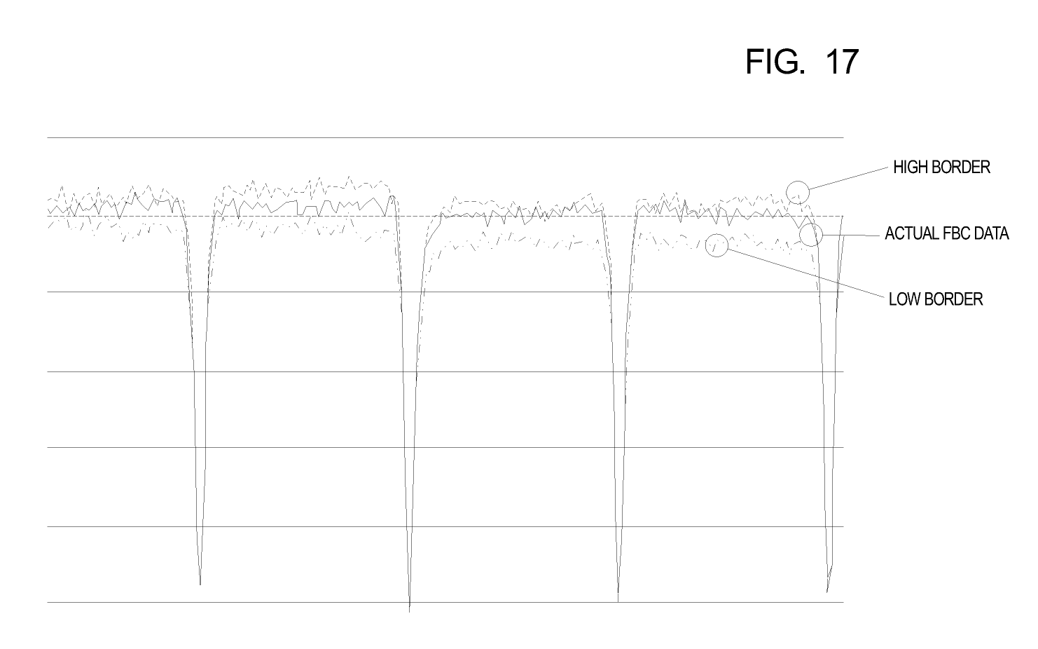

Using functionality of the example cable interface component 120, the example transponder system 72 allows operators to automatically detect changes in RF signal levels resulting from: spurs, noise, tilt, drop-outs, and other undesirable spectral activity. The example transponder system 72 implements this feature as described below with reference to FIG. 17.

Initially, a baseline or “good” spectral pattern is established. This pattern includes a nominal FBC scan with a “band” or range around the nominal values indicating a range of acceptable amplitudes for each scan point. The band or range can be manually configured or can be automatically setup by the SCR function through a set of FBC scans over time. During this setup period, amplitude values at each frequency will be compared to values from prior scans and the high and low values seen throughout the setup period are used as the high and low water marks for the frequency where they were identified. Any range of frequencies can be manually “disabled” (i.e., excluded from ongoing analysis) by configuring a high and low values for that frequency range to the maximum and minimum allowed values respectfully. This is done to create a “dead-band” that will be excluded from ongoing analysis (i.e., no actual FBC value will ever exceed these thresholds) and never contribute to future alarms.

Next, the transponder system 72 runs continuous scans on the defined spectrum to detect any signal amplitude above or below the pre-defined range (i.e., outside the water marks). Next, any scan containing readings outside the “acceptable” range is saved for later analysis. The SCR function can be configured to store offending spectral data using the following options:
First Occurrence—Store a copy of the full spectrum that includes any one or more data points outside the range. In this case, additional spectral data is not stored until directed to restart;
Most Recent Occurrence—Store a copy of the most recent full spectrum that includes any one or more data points outside the range. New copies of the spectral data are stored anytime the spectrum contains an offending data point. In this case, any prior spectral data is overwritten; and/or
Aggregate Occurrences—Store a copy of the full spectral data that includes any one or more data points outside the range. If subsequent FBC scans contain offending data then combine the specific offending data points with the existing stored spectrum IFF the amplitude of the new data is greater than the corresponding amplitude of the stored data. This function produces an aggregate picture of all offending signals in one readable spectral buffer. This serves as a series of overlay snapshots that show all problem areas over time in one picture. The buffer is cleared on a user initiated reset.

Finally, an SNMP trap is sent to the operator identifying the exception. Up to one SNMP trap is sent per spectral capture containing offending data, even if that spectral data contains multiple offending data points.

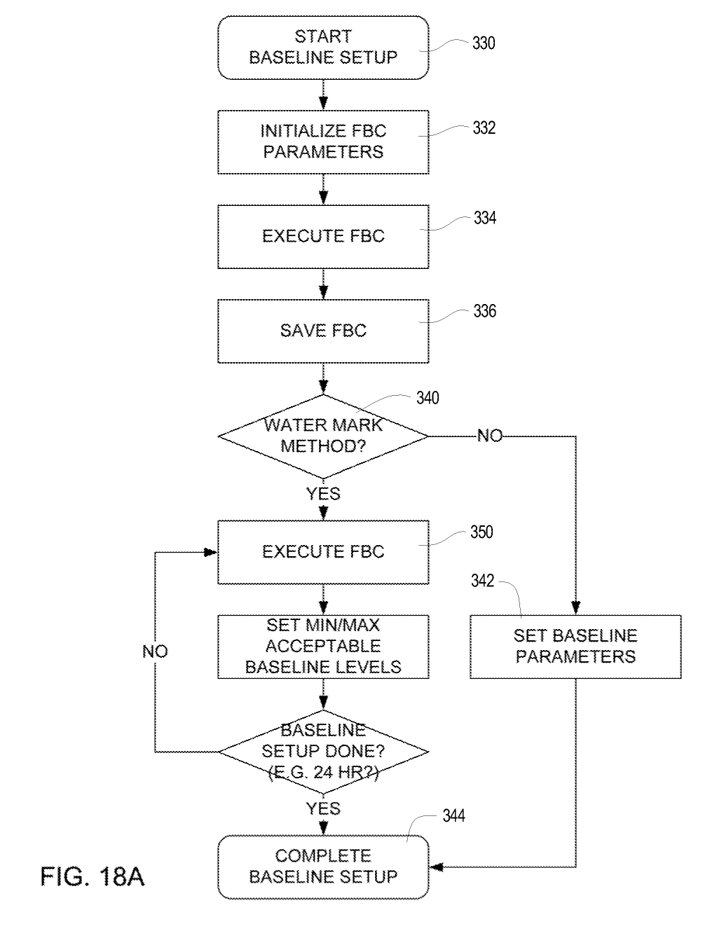

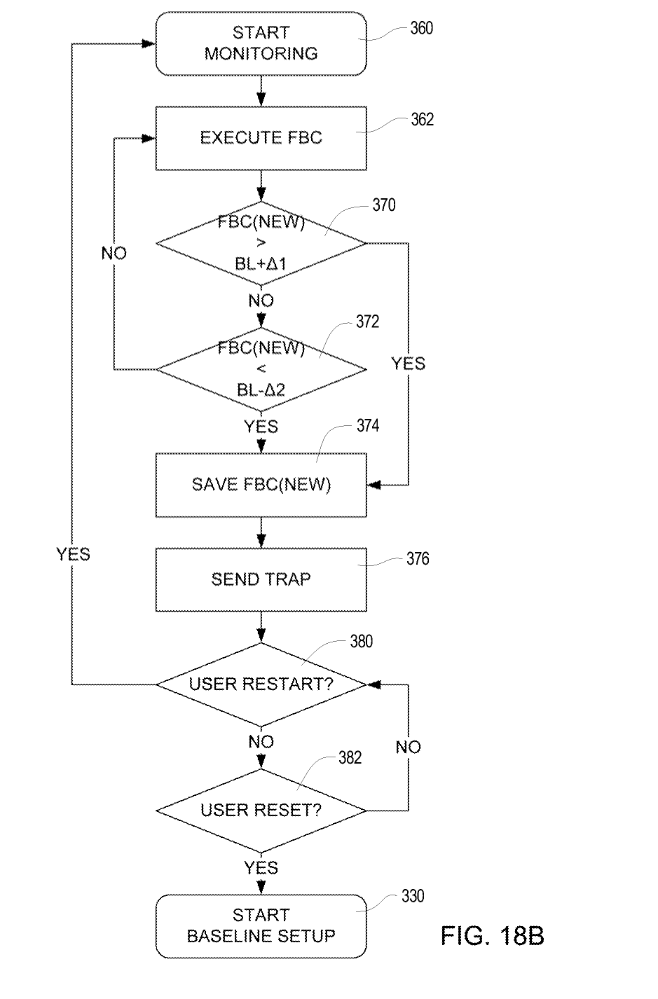

FIGS. 18A and 18B illustrate an example of the logic that may be implemented when automatically detecting changes in RF signal levels resulting from anomalies such as spurs, noise, tilt, drop-outs, and other undesirable spectral activity.

The example transponder system 72 further implements automated data analysis methods to provide cable system operators with early notification of network anomalies. As one example, the example transponder system 72 executes a Capture, Analyze and Notify (CAN) sequence to combine Broadcom's FBC capability with near-real-time data analysis to provide automated network diagnostics. The example CAN sequence performs the following steps:
1. Configure FBC parameters
2. Initiate a FBC
3. Analyze the FBC spectral data for specific data patterns
4. If a targeted data pattern is identified then:
   a. Save a copy of the spectral data and associated reporting metrics for later retrieval and analysis
   b. Send an SNMP Trap indicating which targeted data pattern(s) have been identified
5. Repeat

In general, a baseline is initially calculated as shown in FIG. 18A, and the baseline is used for monitoring in near real-time as shown in FIG. 18B. In particular, one or both of the example power supply 70 and the cable interface component 120 comprises a processor capable of implementing logic steps associated with a base line calculation process and a monitoring process. In particular, as shown in FIG. 5, the example power supply 70 contains a processor 320 capable of implementing the logic and functions associated with FIGS. 18A and 18B.

Referring initially to FIG. 18A, the base line calculation process begins at a step 330. At a step 332, the FBC capture system is initialized. At step 334, the FBC capture process is performed to obtain raw FBC data representative of a reference waveform, and the raw FBC data associated with the reference waveform is saved at step 336 by storing the FBC data in an FBC baseline database.

At step 340, the method determines whether the baseline is to be calculated using the “watermark” method or whether the baseline is to be configured by the utility operating the example communications network 20. If the baseline is to be configured by the operator, the method moves to step 342 at which the user enters a user configured baseline level. The operator may use the raw FBC data stored in the FBC baseline database to generate a user configured baseline level. After the user sets the user configured baseline level, the baseline calculation process is complete and the process proceeds to step 344.

If the baseline is to be configured by using the “watermark” method, after step 340 the method moves to step 350. At step 350, FBC is executed numerous times over a period of time to get high and low threshold levels for the reference waveform. In particular, the raw FBC data is processed by selecting the highest and lowest levels associated with a plurality of waveforms. For each waveform, the highest and lowest levels within predefined bands may be used, in which case the high and low threshold levels may be a composite of the highest and lowest portions of numerous FBC data examples in each of the predefined bands. Further, average, filtered, or smoothed versions of the raw FBC data may be used to reduce the effects of spurious or transient signals. Using the “watermark” method, the baseline level is thus defined by or based on (e.g., average or median) high and low baseline levels that are empirically determined for a particular portion of the example communications network 20 associated with or including the example transponder system 72 including the cable interface module 120.

Alternatively, the baseline level may be defined using the high and low baseline levels calculated from the raw FBC data as a high baseline level and a low baseline level. In this case, the high and low baseline levels are not averaged or otherwise processed to obtain a single baseline level.

Once the baseline setup process is complete and the baseline level (or levels) is set, either by the “watermark” method or by user set parameters, the baseline level (or levels) is stored in the transponder system 72 for future use by a monitoring process implemented by the example transponder system 72. The power supply including the example transponder system 72 is now ready to be used in the monitoring process.

Turning now to FIG. 18B, an example of the monitoring process implemented by the example transponder system 72 will now be described. The monitoring process starts at step 360, after which a FBC is executed at step 362 to generate new FBC data. At steps 370 and 372, the new FBC data is analyzed with reference to the baseline level(s) determined in the base line setup process of FIG. 18A for the presence of waveform characteristics associated with one or more anomalies.

In particular, at step 370 data representing the new FBC signal is compared against an upper threshold level defined by the baseline level plus an offset Δ1. The offset Δ1 may be set such that the upper threshold level is equal to, greater than, or less than the high baseline level empirically determined during the baseline setup process. Further, different offsets Δ1 may be used in different bands within the relevant bandwidth of the FBC signal captured by the cable interface component 120.

Alternatively, if the baseline is determined by high and low baseline levels calculated from the raw FBC data, data representing the new FBC signal is compared at step 370 with the high baseline level. In this case, the high baseline level may be used directly or in combination with an offset to obtain a separate upper threshold level. If an offset is used with the high baseline level, the offset may be zero, positive, or negative, thereby adjusting the upper threshold level relative to the high baseline level as may be desirable for a particular portion of the example communications signal. Again, different offsets may be used in different bands within the relevant bandwidth of the FBC signal captured by the cable interface component 120.

If data representing the new FBC signal show that the new FBC signal is below the upper threshold level (no anomaly), the monitoring process proceeds to step 372. If data representing the new FBC signal show that the new FBC signal is equal to or above the upper threshold level (possible anomaly), the monitoring process proceeds to step 374 at which data representing the new FBC signal is stored as anomaly FBC data in an FBC anomaly database for further processing as will be described in further detail below.

At step 372, the data representing the new FBC signal is compared against a lower threshold level defined by the baseline level minus an offset Δ2. The offset Δ2 may be the same or different than the offset Δ1 and may be set such that the lower threshold level is equal to, greater than, or less than the low baseline level empirically determined during the baseline setup process. As with the example step 370, different offsets Δ2 may be used in different bands within the relevant bandwidth of the FBC signal captured by the cable interface component 120.

If the baseline is determined by separate high and low baseline levels calculated from the raw FBC data, the data representing the new FBC signal is compared at step 372 with the low baseline level. In this case, the low baseline level may be used directly or in combination with an offset to obtain a separate lower threshold level. If an offset is used with the low baseline level, the offset may be zero, positive, or negative, thereby adjusting the lower threshold level relative to the low baseline level as may be desirable for a particular portion of the example communications signal. Again, different offsets may be used in different bands within the relevant bandwidth of the FBC signal captured by the cable interface component 120.

If the data representing the new FBC signal show that the new FBC signal is above the lower threshold level (no anomaly), the monitoring process returns to step 362 and then the process repeats steps 370 and 372. If the data representing the new FBC signal show that the new FBC signal is equal to or below the lower threshold level (possible anomaly), the monitoring process proceeds to step 374. At step 374, the data representing the new FBC signal is stored as anomaly FBC data in the FBC anomaly database for further processing, again as will be described in further detail below.

Steps 370 and 372 thus define a parameter range having upper and lower threshold levels. If the new FBC signal is within that predetermined parameter range, the method returns to step 362 at which a new FBC data is generated and compared to the parameter range at steps 370 and 372. The monitoring process may be executed on command (asynchronously) or periodically. In the example monitoring process depicted in FIG. 18B, the monitoring process is performed multiple times a second and yields near real-time detection of anomalies.

Whenever an anomaly is detected, the data representing the new FBC signal is stored at step 374 as anomaly FBC data and, at step 376, a trap signal (e.g., SNMP trap) is transmitted to a destination such as the headend 24. The trap signal identifies the type of anomaly. Depending on factors such as the type of the anomaly and the frequency at which this type of anomaly occurs, the operator may take appropriate action to repair or replace a failed or degraded system component associated with that type and/or frequency of anomaly.

At a step 380, the operator is given the opportunity to restart the monitoring process by returning to the start monitoring step 360. If the operator elects not to restart at step 380, the monitoring process proceeds to step 382 at which the user is given the opportunity to reset the base line parameters by returning to the start baseline step 330 of the baseline setup process depicted in FIG. 18A. At any point the operator can override the baseline setup process and/or monitoring process as dictated by circumstances. For example, if at least a portion of the example communications system 20 associated with the power supply system 22 is non-operational, the operator may halt the baseline setup and/or monitoring processes.

In addition to saving and analyzing anomaly FBC data, the anomaly FBC data may be compared with previous and future corresponding anomaly FBC data to detect trends that are associated with projected failed or degraded system components even in the absence of a detected anomaly in the FBC data for any single power supply system. Based on these trends, appropriate maintenance may be performed before failure or degradation of system components.

Further, even absent the detection of an anomaly, sample FBC data associated with one power supply system 22 in the communications system 20 may be stored in a sample FBC database and compared with sample FBC data from another power supply system 22 of the communication system 20 to detect certain types of anomalies that may not be apparent by analyzing the FBC data at any single power supply system. For example, if first sample FBC data associated with a first power supply system differs in a substantive way from second sample FBC data associated with a second power supply system downstream of the first power supply system, even if neither the first nor the second FBC data corresponds to an anomaly, a difference between the first and second sets of FBC data may be associated with an anomaly that requires repair or maintenance.

In addition, the monitoring process may be configured to monitor characteristics of the FBC data for different types of anomalies and more than one type of anomaly at a time. In particular, the monitoring process may be configured to monitor characteristics in addition to or instead of high/low threshold levels such as overall shape of the waveform, slope of any portion of the waveform, discontinuities in the waveform. Additional steps similar to steps 360 and 362 may be executed in series or alternately with steps 360 and 362 to analyze the new FBC data for these other types of anomalies. The setting of reference levels may be automated in a manner similar to that of FIG. 18A, may be set by the operator as described in FIG. 18A, or may be a combination of setting thresholds and manually identifying and quantifying visual characteristics such as waveform shape, waveform slope, and/or waveform discontinuities.

The example transponder system 72 including the cable interface module 120 thus is configured to detect anomalies in the communications network 20 automatically and in real-time or near real-time. In addition, the example transponder system is capable of sending commands to the headend 24 or any other node in the communications network 20 to allow steps to be taken as necessary to repair the anomaly.

Examples of the data patterns that the FBD system will identify will be discussed below.

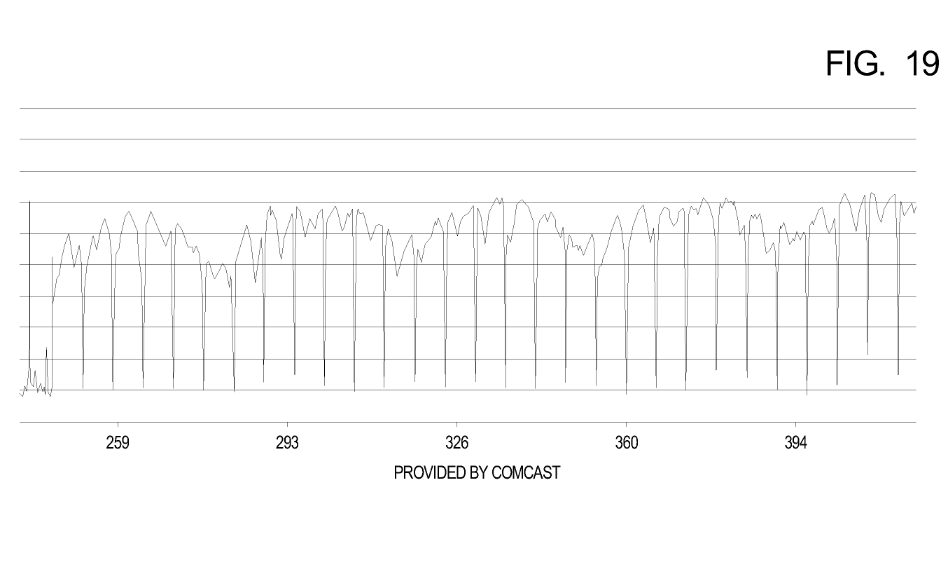

FIG. 19 illustrates a data pattern that may be analyzed when performing Frequency Response Ripple Analysis. When performing Frequency Response Ripple Analysis, periodic, repeating standing waves are identified. The typical cause of such periodic, repeated standing waves is an impedance mismatch.

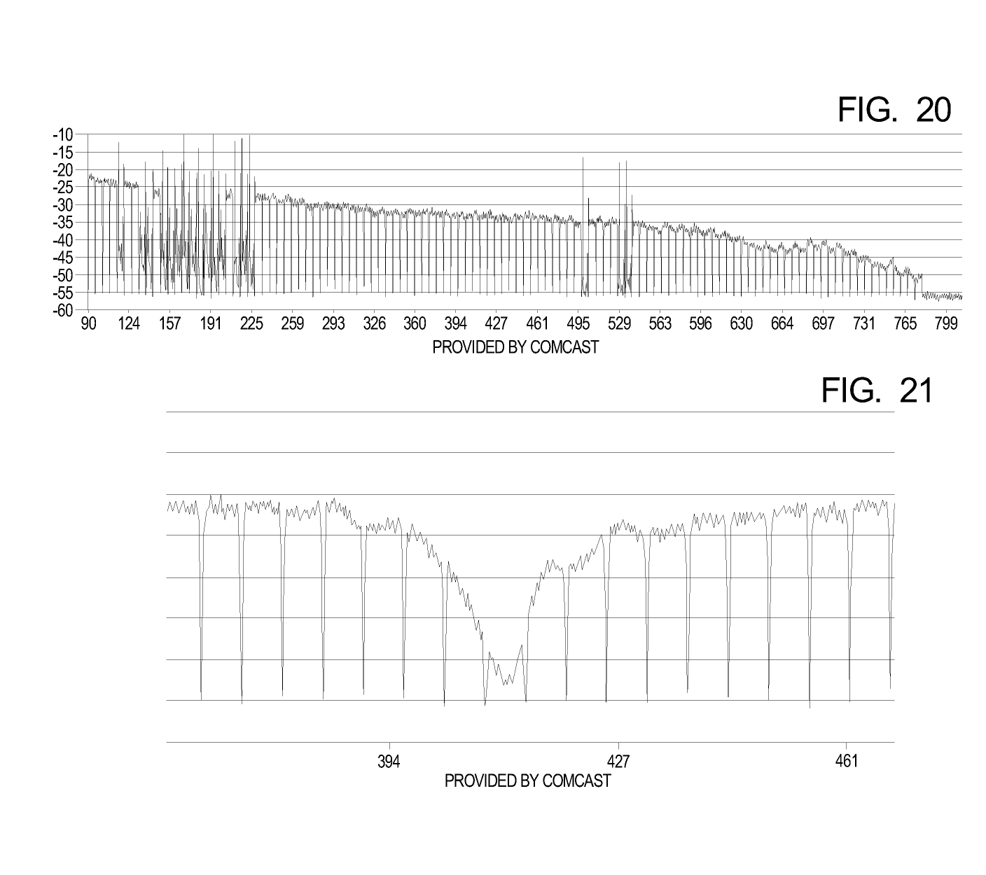

FIG. 20 illustrates the use of spectral tilt analysis to identify linear variation in spectral energy across the measured spectrum.

FIG. 21 illustrates a data pattern representative of frequency suck-out that may be determined by notch analysis. The data pattern represented in FIG. 21 depicts a concave notch representative of a frequency specific lack of power.

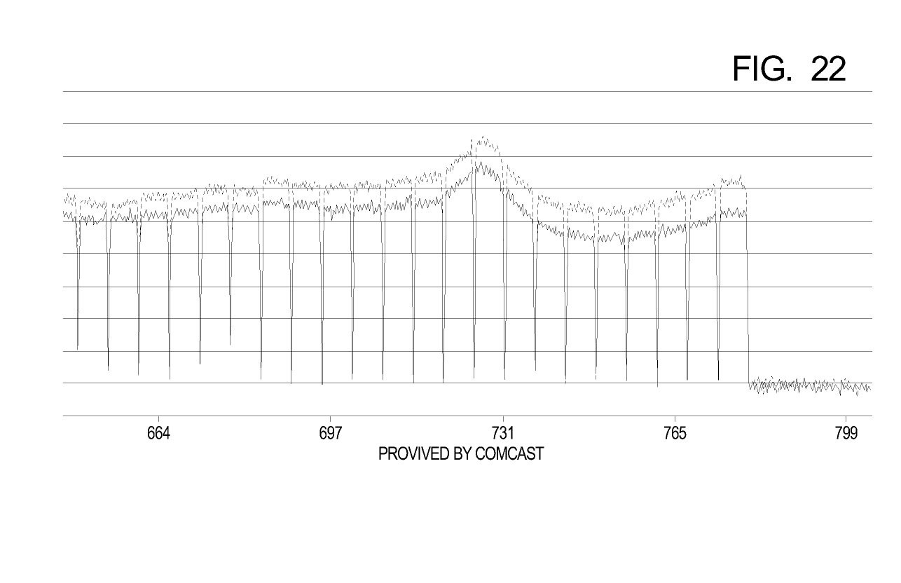

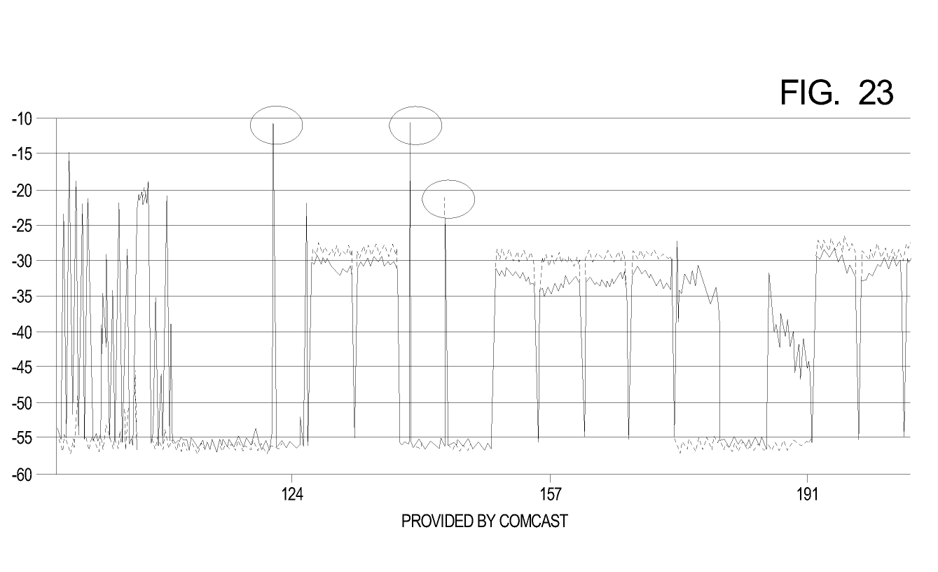

FIG. 22 illustrates the use of frequency spike analysis to identify frequency spectral amplification caused by faulty amplifiers.

Level variation analysis may be performed to determine the time specific change in signal level over an entire band, often characterized by power level changes at a specific frequency such as 120 Hz. Such time specific changes in signal may be best analyzed using rapid, successive scans. Time specific changes in signal may indicate faulty or poorly designed AGC's, and lightning damaged couplers may allow AC power coupling onto the signal carrier.

FIG. 23 illustrates the use of ingress carrier analysis to determine the “ingress” of LTE, FM, UHF, and other frequency specific signals onto the coaxial cable system. The cause of the ingress of such signals is often faulty shielding. The ingress of extraneous signals may be visible only sporadically and for short durations or bursts when the source of the ingress signal is active.

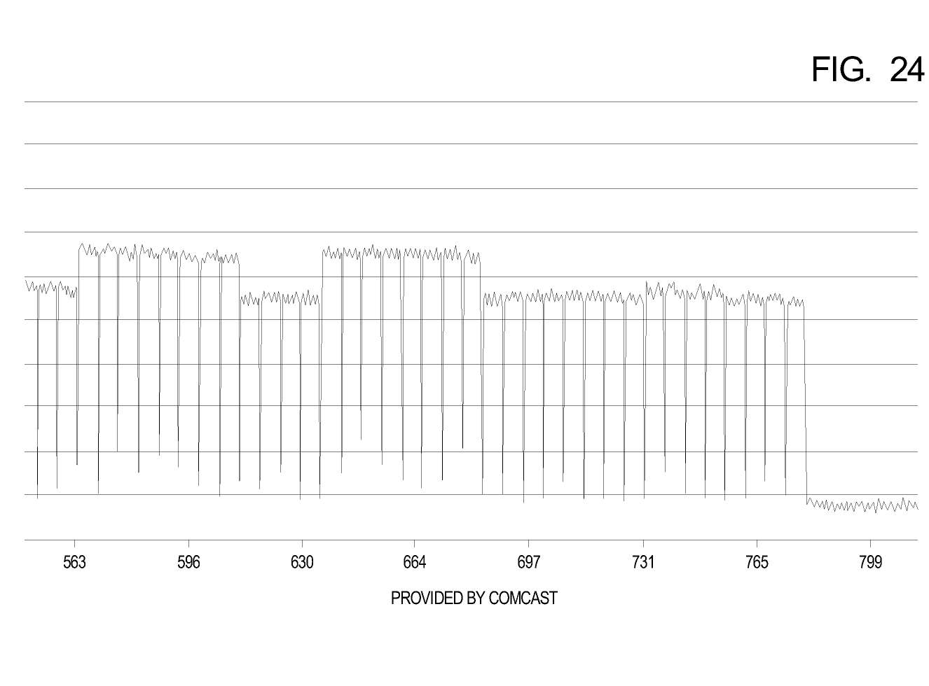

FIG. 24 illustrates the use of relative channel level analysis to determine whether a channel is either too high or too low relative to adjacent channels.

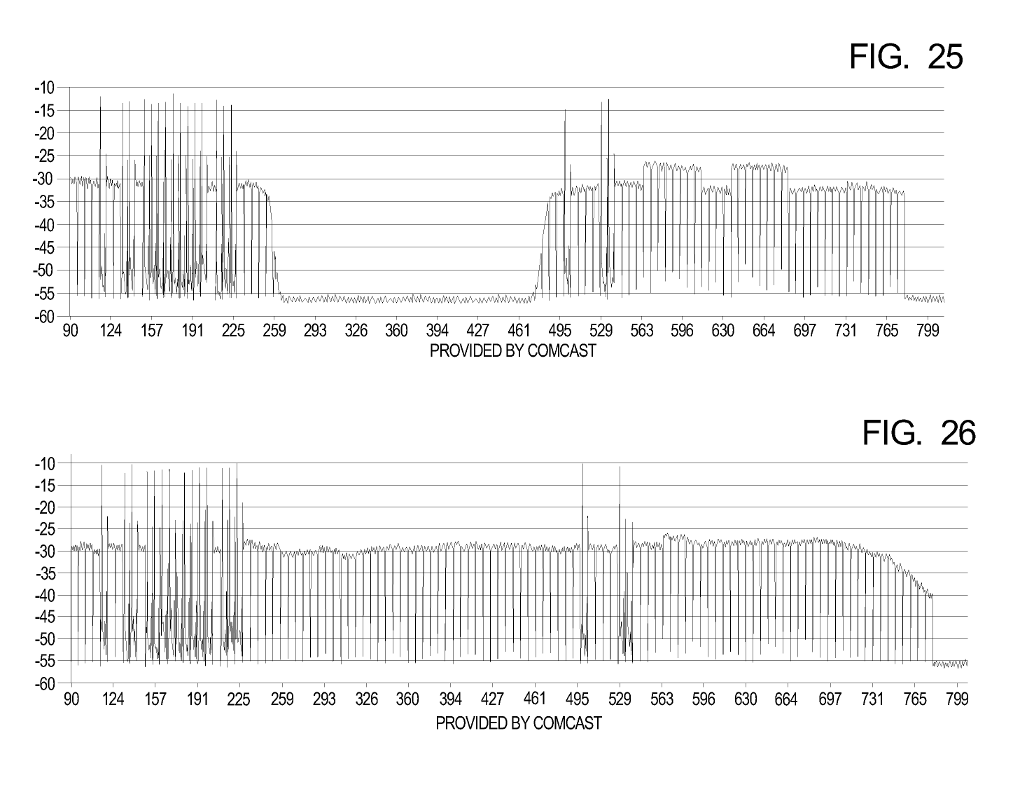

FIG. 25 illustrates the use of dropped channel(s) analysis to determine whether a channel level has dropped to ˜0 level. In this case, the signal for one or multiple channels is no longer present. Dropped channels may be contiguous as shown or not contiguous. A dropped channel is typically indicative of a faulty edge QAM device.

FIG. 26 illustrates the use of dropped channel(s) analysis to determine whether a channel level has dropped to ˜0 level. In this case, the signal for one or multiple channels is no longer present. Dropped channels may be contiguous as shown or not contiguous. A dropped channel is typically indicative of a faulty edge QAM device.

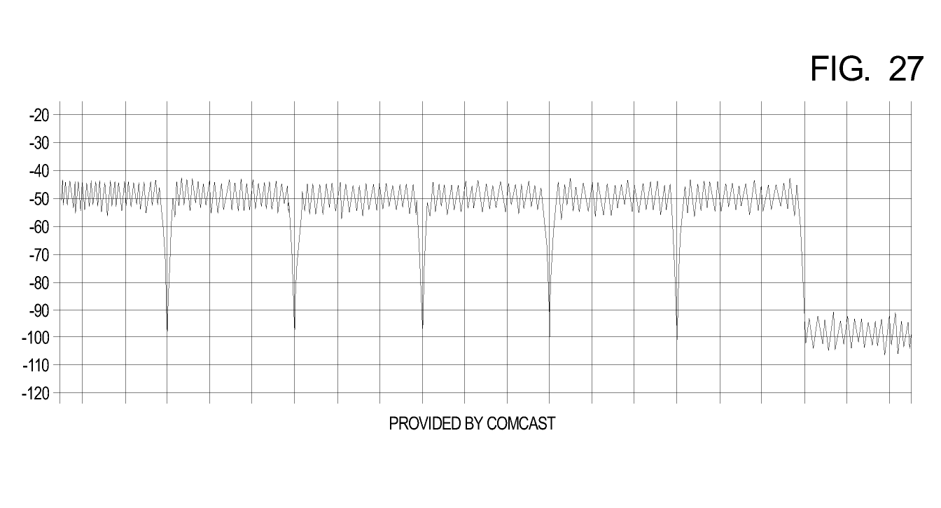

FIG. 27 illustrates the use of frequency roll-off analysis to analyze the signal for the existence of non-linear amplitude drop at the edge of measured spectrum by detecting frequency specific power loss.

FIG. 28 illustrates the use of individual channel analysis to review each QAM channel for any anomalous measurements. The display is set to high resolution scan and factors such as equalizer data, ripple, channel MER, ingress under carrier (LTE), are reviewed for each channel. In particular, each channel may be analyzed to determine channel number, Center frequency, channel width, in channel frequency response, MER, MER measure type, channel power, tilt level, tilt bias, ripple count, ripple amplitude, low bin pointer, and high bin pointer.

### Glossary

| Term | Definition |
|---|---|
| Transponder | The product(s) defined by this specification inclusive of all |
| | individual models or sub-models defined herein. Unless defined |
| | otherwise, a requirement applied to “transponder”SHALL apply |
| | to all models of transponders defined herein. |
| CM | Refers to the DOCSIS Cable Modem (CM) microcontroller, firmware |
| | and functionality |
| Cable | Cable modem termination system, located at the cable television |
| Modem | system head-end or |
| Termination | distribution hub, which provides complementary functionality to |
| System | the cable modems to |
| (CMTS) | enable data connectivity to a wide-area network |
| FBC | Full Band Capture is the capability to analyze the downstream |
| | CATV spectrum from 50 MHz to 1 Ghz utilizing the Broadcom |
| | 3383 series FBC capability. |
| Micro- | Echoes in the forward or reverse transmission path due to |
| reflections | impedance mismatches between the physical plant components. |
| | Micro-reflections are distinguished from discrete echoes by |
| | having a time difference (between the main signal and the echo) |
| | on the order of 1 microsecond. Micro-reflections cause |
| | departures from ideal amplitude and phase characteristics for the |
| | transmission channel. |
| Network | The hardware and software components used by the Network |
| Management | Provider to manage its networks as a whole. The Network |
| System | Management System provides an end-to-end network view of the |
| (NMS) | entire network enabling management of the network elements |
| | contained in the network. |
| QoS | Quality of Service refers to the transponder's ability to monitor |
| | and report network parameters for network health and diagnostic |
| | reporting. |
| Simple | A network management protocol ofthe IETF |
| Network | |
| Management | |
| Protocol | |
| (SNMP) | |
| SNMP Agent | The term “agent”refers to 1) a SNMPv1/v2 agent or 2) a |
| | SNMPv3 entity [RFC3411] which contains command responder |
| | and notification originator applications. |
| SNMP | The term “manager”is used throughout this section to refer to 1) |
| Manager | a SNMPv1/v2 manager or 2) a SNMPv3 entity [RFC3411] which |
| | contains command generator and/or notification receiver |
| | applications. |
| Upstream | The direction from the subscriber location toward the head-end. |
| (US) | |
| FBC | Full Band Capture. Full spectrum data capture, allowing |
| | subsequent analysis for network diagnostics. |
| FBD | Full Band Diagnostics. Generically used herein to describe the |
| | complete set of network diagnostics tools. |
| FFT | Fast Fourier Transform. An algorithm to compute the Discrete |
| | Fourier Transform (DFT) and its inverse. Used to convert |
| | between time and frequency domains for displaying RF |
| | diagnostics information. |
| Near-Real- | A term used to describe the data analysis method. In practice, |
| Time | FBC data is analyzed and patterns of interest are identified and |
| | reported as quickly the information can be processed. A specific |
| | real-time requirement implies data analysis occurs at the speed |
| | of the actual event and that could be identified using real-time RF |
| | signal information. The “near” real-time designation indicates |
| | that the data analysis method is not intended as a substitute for |
| | real-time test and measurement equipment (spectrum analyzer, |
| | QAM analyzer, etc.). |
| SCTE 40 | The SCTE standard that defines the characteristics and |
| | normative specifications for the digital network interface between |
| | a cable television system and commercially available digital |
| | cable products that are used to access multi-channel television |
| | programming. |

What is claimed is:

1. A power supply system for use in a communications system comprising:
a power supply connected to a local supply, a utility supply, and the communications system;
a cable interface module for detecting an FBC signal associated with the communications system; and
a processor that executes a monitoring process in which the processor monitors the FBC signal for characteristics associated with at least one anomaly, and generates a trap signal when an anomaly is detected.

2. A power supply system as recited in claim 1, in which, when an anomaly is detected, the processor further stores data associated with the FBC signal associated with the anomaly as anomaly FBC data.

3. A power supply system as recited in claim 1, in which the processor monitors the FBC signal for characteristics associated with a plurality of anomalies.

4. A power supply system as recited in claim 1, in which the processor monitors the FBC signal for characteristics associated with at least one anomaly by comparing data associated with the FBC signal with at least one baseline level.

5. A power supply system as recited in claim 4, in which processor monitors the FBC signal for characteristics associated with at least one anomaly by:
determining whether the FBC signal is greater than the sum of the at least one baseline level and a first offset value; and
determining whether the FBC signal is less than the at least one baseline level less a second offset value.

6. A power supply system as recited in claim 4, in which processor compares the data associated with the FBC signal with first and second baseline levels by:
determining whether the FBC signal is greater than the first baseline level; and
determining whether the FBC signal is less than a second baseline level.

7. A power supply as recited in claim 1, in which the processor monitors the FBC signal for characteristics associated with at least one anomaly by comparing the FBC signal with at least one other FBC signal.

8. A power supply as recited in claim 1, in which the at least one other FBC signal is detected at another point in time than the FBC signal.

9. A power supply as recited in claim 1, in which the at least one other FBC signal is detected at another location than the FBC signal.

10. A power supply as recited in claim 1, in which the processor further executes a base line setup process in which the processor determines at least one baseline level.

11. A power supply as recited in claim 10, in which the processor determines the at least one baseline level using a watermark process.

12. A power supply as recited in claim 10, in which the processor allows a user to set the at least one baseline level.

13. A method of providing power to a communications system comprising the steps of:
connecting a power supply to a local supply, a utility supply, and the communications system;
arranging a cable interface module to detect an FBC signal associated with the communications system;
monitoring the FBC signal for characteristics associated with at least one anomaly; and
generating a trap signal when an anomaly is detected.

14. A method as recited in claim 13, further comprising the step of storing data associated with the FBC signal associated with the anomaly as anomaly FBC data when an anomaly is detected.

15. A method as recited in claim 13, in which the step of monitoring the FBC signal for characteristics associated with at least one anomaly comprises the step of comparing data associated with the FBC signal with at least one baseline level.

16. A method as recited in claim 15, in which the step of monitoring the FBC signal for characteristics associated with at least one anomaly comprises the steps of:
determining whether the FBC signal is greater than the sum of the at least one baseline level and a first offset value; and
determining whether the FBC signal is less than the at least one baseline level less a second offset value.

17. A method as recited in claim 15, in which the step of comparing the data associated with the FBC signal with first and second baseline levels comprises the steps of:
determining whether the FBC signal is greater than the first baseline level; and
determining whether the FBC signal is less than a second baseline level.

18. A method as recited in claim 17, further comprising the step of executing a base line setup process in which the processor determines at least one baseline level.

19. A method as recited in claim 17, in which the step of determining the at least one baseline level employs a watermark process.

20. A method as recited in claim 17, in which the step of determining the at least one baseline level comprises the step of allowing a user to set the at least one baseline level.
